(19) United States
(12) Patent Application Publication
(10) Pub. No.: US 2026/0135638 A1
(43) Pub. Date: May 14, 2026

(54) Techniques for Iterative Soft-Decision Decoding

(71) Applicant: Apple Inc., Cupertino, CA (US)

(72) Inventors: Linbo Li, San Diego, CA (US); Mohamad Mansour, San Jose, CA (US); Louay Jalloul, San Jose, CA (US)

(73) Assignee: Apple Inc., Cupertino, CA (US)

(21) Appl. No.: 19/327,968

(22) Filed: Sep. 12, 2025

Related U.S. Application Data
(60) Provisional application No. 63/720,674, filed on Nov. 14, 2024.

(51) Int. Cl. H04L 1/00; H03M 13/37; H03M 13/45

(52) U.S. Cl. CPC H04L 1/005; H03M 13/3746; H03M 13/45

(57) ABSTRACT

Techniques are described herein for iterative decoding. An example method can include iteratively decoding a codeword by at least: determining soft channel reliability information values for bits of the codeword in a decoding iteration k, sorting the soft channel reliability information values, generating soft extrinsic information for the codeword based on a belief-propagation technique wherein the soft extrinsic information is based on the sorted channel reliability information values, and passing the soft extrinsic information to a decoding iteration k+1, such that soft channel reliability information for the decoding iteration k+1 is updated based on the soft extrinsic information for the codeword. The method can further include determining whether iteratively decoding the codeword is successful based on the updated soft channel reliability information, wherein the codeword was generated using a Reed-Muller encoding technique.

### CROSS-REFERENCES TO RELATED APPLICATIONS

This application claims the benefit of U.S. Provisional Application No. 63/720,674, filed on Nov. 14, 2024, which is incorporated by reference.

### BACKGROUND

Cellular communications can be defined in various standards to enable communications between a user equipment and a cellular network. For example, a long-term evolution (LTE) network, Fifth generation mobile network (5G), and Sixth generation mobile network (6G, which is being developed) are wireless standards that aim to improve upon data transmission speed, reliability, availability, and more.

### BRIEF DESCRIPTION OF THE DRAWINGS

FIG. 1 illustrates an example network environment, according to one or more embodiments.

FIG. 2 is an illustration of example system for error detection and correction, according to one or more embodiments.

FIG. 3 is an illustration of an example receiver chain, according to one or more embodiments.

FIG. 4 is an illustration of belief propagation nodes, according to one or more embodiments.

FIG. 5 illustrates a plot of example simulation results, according to one or more embodiments.

FIG. 6 illustrates a plot of example simulation results, according to one or more embodiments.

FIG. 7 illustrates tables of example simulation results, according to one or more embodiments.

FIG. 8 illustrates plots of example simulation results, according to one or more embodiments.

FIG. 9 is an example process for soft-decision decoding, according to one or more embodiments.

FIG. 10 is an example process for soft-decision decoding, according to one or more embodiments.

FIG. 11 is an illustration of an example receive components, according to one or more embodiments.

FIG. 12 is an illustration of an example of a user equipment (UE), in accordance with some embodiments.

FIG. 13 is an illustration of an example of a network node, in accordance with some embodiments.

### DETAILED DESCRIPTION

Networking systems can use error correction codes to detect and correct errors in data transmission. The error correction codes can add redundancy to the original data, enabling a computing system to detect and correct errors without requiring the transmission of additional messages. Error correction codes can enhance the reliability and accuracy of data communication systems, especially in environments with high noise levels or potential data corruption.

Reed-Muller codes are a class of error correction codes that can be effective for detecting and correcting errors. Reed-Muller codes are conjectured to achieve Shannon capacity on a binary memoryless symmetric channel. Reed-Muller codes can achieve the capacity of erasure channels owing to their large symmetry group. Reed-Muller codes can share similarities with polar codes (e.g., under a factor-graph representation). There are differences between polar codes and Reed-Muller codes. Reed-Muller codes are designed to maximize the minimum distance among the codewords. Polar codes are designed to minimize error probability under successive cancellation (SC) or SC list decoding. Code construction of Reed-Muller codes can be channel-independent (achieving capacity universally), which may not impose additional complexity when the codes are constructed for different communication mediums, even under variable channel conditions, while polar codes may have channel-dependent construction. Furthermore, Reed-Muller codes may have better error detection and correction performance than polar codes for shorter block lengths. Additionally, codewords encoded using Reed-Muller codes can be decoded with efficient algorithms (e.g., Dumer Fast Hadamard Transform (FHT), recursive projection aggregation (RPA), path-metric). This may be relevant for cellular control channel (CCH) design. A networking system can also be enabled with advanced techniques improved Reed-Muller decoding (e.g., successive permutation-based algorithms, construction of stronger subcodes). A networking system can attain error detection and correction using Reed-Muller codes for short block lengths.

The herein described decoder can iteratively use soft extrinsic information to enable a significant performance improvement when compared against a conventional decoding, and also provides a tool to utilize soft extrinsic information for enhanced error correction for Reed-Muller-based codewords.

The following detailed description refers to the accompanying drawings. The same reference numbers may be used in different drawings to identify the same or similar elements. In the following description, for purposes of explanation and not limitation, specific details are set forth, such as particular structures, architectures, interfaces, techniques, etc., in order to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail. For the purposes of the present document, the phrase “A or B” means (A), (B), or (A and B); and the phrase “based on A” means “based at least in part on A,” for example, it could be “based solely on A” or it could be “based in part on A.”

The following is a glossary of terms that may be used in this disclosure.

The term “circuitry” as used herein refers to, is part of, or includes hardware components such as an electronic circuit, a logic circuit, a processor (shared, dedicated, or group) or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable system-on-a-chip (SoC)), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” as used herein refers to, is part of, or includes circuitry capable of sequentially and automatically carrying out a sequence of arithmetic or logical operations, or recording, storing, or transferring digital data. The term “processor circuitry” may refer to an application processor, baseband processor, a central processing unit (CPU), a graphics processing unit, a single-core processor, a dual-core processor, a triple-core processor, a quad-core processor, or any other device capable of executing or otherwise operating computer-executable instructions, such as program code, software modules, or functional processes.

The term “user equipment” or “UE” as used herein refers to a device with radio communication capabilities and may describe a remote user of network resources in a communications network. The term “user equipment” or “UE” may be considered synonymous to, and may be referred to as, client, mobile, mobile device, mobile terminal, user terminal, mobile unit, mobile station, mobile user, subscriber, user, remote station, access agent, user agent, receiver, radio equipment, reconfigurable radio equipment, reconfigurable mobile device, etc. Furthermore, the term “user equipment” or “UE” may include any type of wireless/wired device or any computing device including a wireless communications interface.

The term “base station” as used herein refers to a device with radio communication capabilities, that is a network component of a communications network (or, more briefly, a network), and that may be configured as an access node in the communications network. A UE's access to the communications network may be managed at least in part by the base station, whereby the UE connects with the base station to access the communications network. Depending on the radio access technology (RAT), the base station can be referred to as a gNodeB (gNB), eNodeB (eNB), access point, etc.

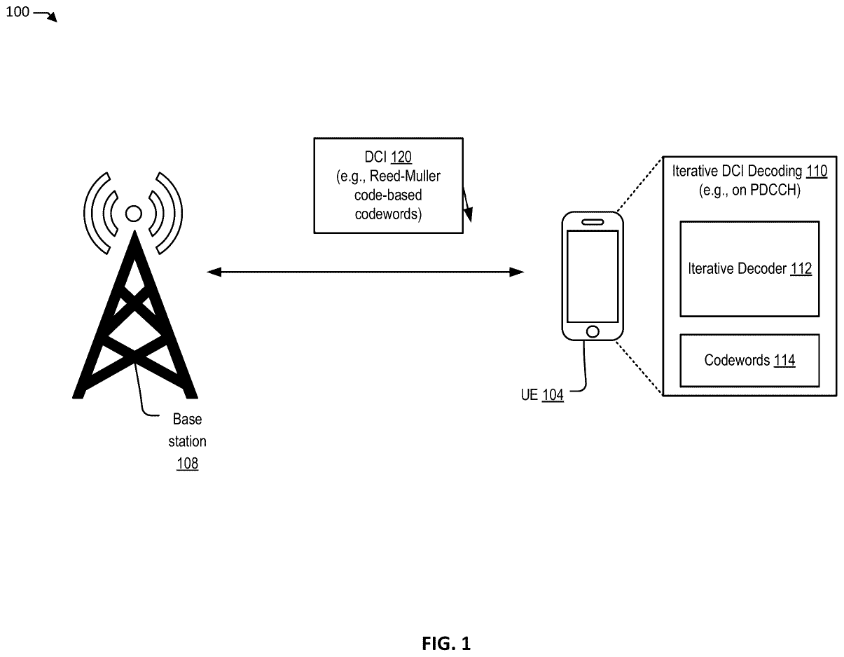

FIG. 1 is an illustration of an example network environment 100, in accordance with some embodiments. The network environment 100 may include a UE 104 and a base station 108. The base station 108 provides a wireless access cell; for example, a Third-Generation Partnership Project (3GPP) New Radio (NR) cell, through which the UE 104 may communicate with the base station 108. The base station 108 may include a set of transmission and reception points (TRPs). The UE 104 and the base station 108 may communicate over an interface compatible with 3GPP technical specifications, such as those that define Fifth-Generation (5G) NR system standards, Sixth-Generation (6G) standards, or the like.

The base station 108 may transmit information (for example, data and control signaling) in the downlink direction by mapping logical channels on the transport channels, then transport channels onto physical channels. The logical channels may transfer data between a radio link control (RLC) and media access control (MAC) layers; the transport channels may transfer data between the MAC and PHY layers; and the physical channels may transfer information across the air interface. The physical channels may include a physical broadcast channel (PBCH); a physical downlink control channel (PDCCH); and a physical downlink shared channel (PDSCH).

The PBCH may be used to broadcast system information that the UE 104 may use for initial access to a serving cell. The PBCH may be transmitted along with physical synchronization signals (PSS) and secondary synchronization signals (SSS) in a synchronization signal (SS)/PBCH block. The SS/PBCH blocks (SSBs) may be used by the UE 104 during a cell search procedure and for beam selection.

The PDSCH may be used to transfer end-user application data, signaling radio bearer (SRB) messages, system information messages (other than, for example, MIB), and paging messages.

The PDCCH may transfer downlink control information (DCI) that is used by a scheduler of the base station 108 to allocate both uplink and downlink resources. The DCI may also be used to provide uplink power control commands, configure a slot format, or indicate that preemption has occurred.

The base station 108 may also transmit various reference signals to the UE 104. The reference signals may include demodulation reference signals (DMRSs) for the PBCH, PDCCH, and PDSCH. The UE 104 may compare a received version of the DMRS with a known DMRS sequence that was transmitted to estimate an impact of the propagation channel. The UE 104 may then apply an inverse of the propagation channel during a demodulation process of a corresponding physical channel transmission.

The reference signals may also include a CSI reference signal (CSI-RS). The CSI-RS may be a multi-purpose downlink transmission signal that may be used for CSI reporting, beam management, connected mode mobility, radio link failure detection, beam failure detection and recovery, and fine-tuning of time and frequency synchronization.

The reference signals and information from the physical channels may be mapped to resources of a resource grid. There is one resource grid for a given antenna port, subcarrier spacing configuration, and transmission direction (for example, downlink or uplink). The basic unit of an NR downlink resource grid may be a resource element, which may be defined by one subcarrier in the frequency domain, and one orthogonal frequency division multiplexing (OFDM) symbol in the time domain. Twelve consecutive subcarriers in the frequency domain may compose a physical resource block (PRB). A resource element group (REG) may include one PRB in the frequency domain, and one OFDM symbol in the time domain, for example, twelve resource elements. A control channel element (CCE) may represent a group of resources used to transmit PDCCH. One CCE may be mapped to a number of REGs; for example, six REGs.

Transmissions that use different antenna ports may experience different radio channels. However, in some situations, different antenna ports may share common radio channel characteristics. For example, different antenna ports may have similar Doppler shifts, Doppler spreads, average delay, delay spread, or spatial receive parameters (for example, properties associated with a downlink received signal angle of arrival at a UE). Antenna ports that share one or more of these large-scale radio channel characteristics may be said to be quasi co-located (QCL) with one another. 3GPP has specified four types of QCL to indicate which particular channel characteristics are shared. In QCL Type A, antenna ports share Doppler shift, Doppler spread, average delay, and delay spread. In QCL Type B, antenna ports share Doppler shift and Doppler spread. In QCL Type C, antenna ports share Doppler shift and average delay. In QCL Type D, antenna ports share spatial receiver parameters.

The base station 108 may provide transmission configuration indicator (TCI) state information to the UE 104 to indicate QCL relationships between antenna ports used for reference signals (for example, synchronization signal/PBCH or CSI-RS) and downlink data or control signaling (for example, PDSCH or PDCCH). The base station 108 may use a combination of RRC signaling, MAC control element signaling, and DCI, to inform the UE 104 of these QCL relationships.

The UE 104 may transmit data and control information to the base station 108 using physical uplink channels. Different types of physical uplink channels are possible, including a physical uplink control channel (PUCCH) and a physical uplink shared channel (PUSCH). Whereas the PUCCH carries control information from the UE 104 to the base station 108, such as uplink control information (UCI), the PUSCH carries data traffic (e.g., end-user application data) and can carry UCI.

In an example, communications with the base station 108 can use channels in the frequency range 1 (FR1) band and/or frequency range 2 (FR2) band, although other frequency ranges are possible. The FR1 band includes a licensed band and an unlicensed band. The NR unlicensed band (NR-U) includes a frequency spectrum that is shared with other types of radio access technologies (RATs) (e.g., LTE-LAA, WiFi, etc.). A listen-before-talk (LBT) procedure can be used to avoid or minimize collision between the different RATs in the NR-U, whereby a device applies a clear channel assessment (CCA) check before using the channel.

The UE 104 can be located within a network coverage. In particular, the base station 108 may provide the network coverage with signaling (e.g., which may be carried by one or more beams). The network coverage may represent a cell or a portion of the cell that the base station 108 provides. The network coverage may provide network connections to multiple UEs, similar to the UE 104. These UEs may communicate with the base station 108 on both the uplink and the downlink based on channels available to them when the UEs are in the network coverage.

In an example, the UE 104 supports carrier aggregation (CA), whereby the UE 104 can connect and exchange data simultaneously over multiple component carriers (CCs) with the base station 108. The CCs can belong to the same frequency band, in which case they are referred to as intra-band CCs. Intra-band CCs can be contiguous or non-contiguous. The CCs can also belong to different frequency bands, in which case they are referred to as inter-band CCs. A serving cell can be configured for the UE 104 to use a CC. A serving cell can be a primary (PCell), a primary secondary cell (PSCell), or a secondary cell (SCell). Multiple SCells can be activated via an SCell activation procedures where the component carriers of these serving cells can be intra-band contiguous, intra-band noon-contiguous, or inter-band. The serving cells can be collocated or non-collocated.

The UE 104 can also support dual connectivity (DC), where it can simultaneously transmit and receive data on multiple CCs from two serving nodes or cell groups (a master node (MN) and a secondary node (SN)). DC capability can be used with two serving nodes operating in the same RAT or in different RATs (e.g., an MN operating in NR, while an SN operates in LTE). These different DC modes include, for instance, evolved-universal terrestrial radio access-new radio (EN)-DC, NR-DC, and NE-DC (the MN is a NR gNB and the SN is an LTE eNB).

As further described in connection with the next figures, the base station 108 can send DCI 120 in PDCCH to the UE 104. The UE 104 can perform blind DCI decoding 110 on the PDCCH to determine the DCI 120.

In one example, the base station 120 (e.g., an RF transmit chain thereof, or a component of this chain such as an encoder) encodes the DCI 120 using an encoding algorithm (e.g., one for polar codes). Accordingly, the actual signals that are transmitted represent one or more codewords that encode the DCI 120 and that enable error detection and correction at the UE 104.

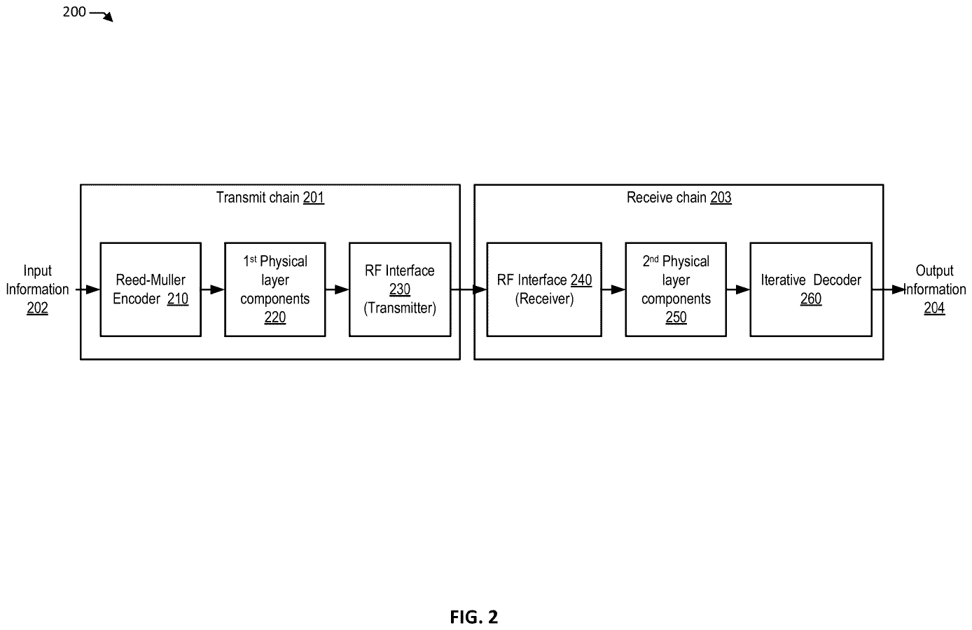

FIG. 2 is an illustration of example system 200 for error detection and correction in accordance with some embodiments. As illustrated, the system 200 includes a transmit chain 201 and a receive chain 203 for a downlink path. The transmit chain 201 can be included in a radio frequency front end of a base station for processing information 202 (including DCI) and transmitting signals that represent the information 202 to UEs. The receive chain 203 can be included in a radio frequency front end of a UE for receiving and processing such signals to determine information 204. Equivalently for an uplink path, a similar transmit chain can be included in the UE (e.g., for transmitting UCI or other information) and a similar receive chain can be included in the base station (e.g., for receiving such information).

Error detection and/or correction can be implemented such that the information 204 is the same as the information 202 or any resulting error rate is smaller than an acceptable threshold error rate. To do so, the transmit chain 201 can include a Reed-Muller encoder 210, whereas the receive chain can include an iterative decoder 260.

In an example, the Reed-Muller encoder 210 can process bits that represent the input information 202 (e.g., bits) at a block level (e.g., in information blocks). Bits that represent an information block can be encoded using Reed-Muller codes to generate one or more codewords. The generated codewords can be passed to first physical layer components 220 of the transmit chain 201, such as a scrambler, a modulator, a precoder, and/or a resource element mapper, such that the codewords can be modulated and mapped onto resource elements. An RF interface 230 of the transmit chain (e.g., a transmitter coupled with a set of antennas) can then output the corresponding signals.

The signals can be received by an RF interface 240 of the receive chain 203 (e.g., a receiver coupled with a set of antennas). Following a set of operations (e.g., amplifying, frequency shifting, filtering, analog to digital conversion, etc.), second physical layer components 250 of the receive chain 201 (e.g., descrambler, demodulator, etc.) can output candidate codewords to iterative decoder 260 that in turn decodes the candidate codewords and, if the decoding is successful, can output bits that represent the output information 204 (e.g., bits).

In an example, the input to the iterative decoder 260 includes soft bits. A soft bit can represent a binary value (e.g., a one or zero) and a likelihood of that value to be correct (e.g., a log likelihood ratio (LLR)). A group of soft bits can correspond to a symbol (which may depend on the modulation technique). The output of the batch dynamic successive cancellation flip decoder 260 can be a hard decoding decision: a binary value (e.g., a one or a zero) for each bit if the decoding is successful.

In an example, the input information 202 includes DCI. The iterative decoder 260 can be used for DCI decoding. In this case, a maximum candidate number codewords can be decoded. This maximum number can be, for example, forty-four in the use case of a 5G NR system.

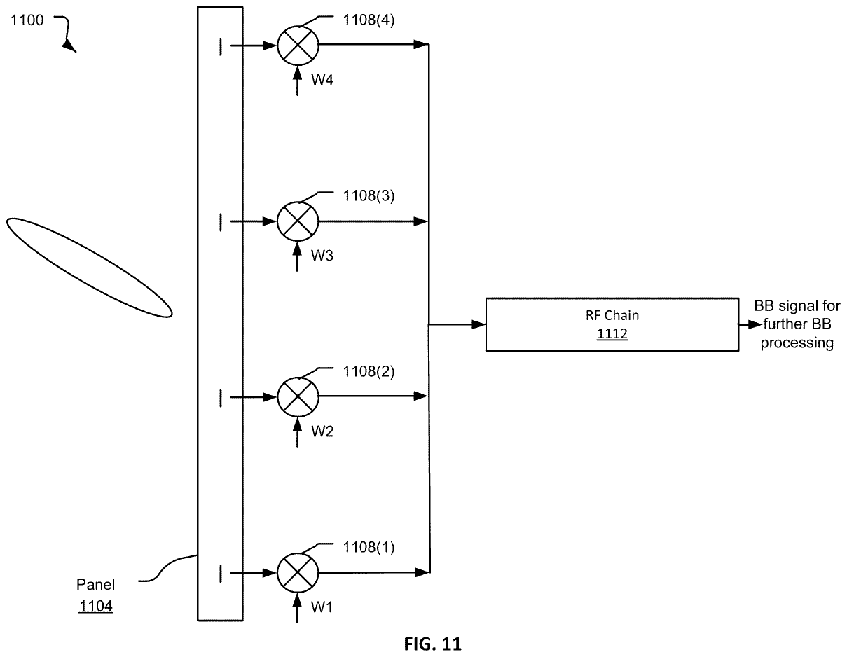

The herein described decoder not only provides a significant performance improvement when compared against a conventional decoding, but also provides a tool to utilize soft extrinsic information for enhanced error correction. The UE 104 (e.g., an RF receive chain thereof) can receive and process the signals. Due to noise, interference, and other signals, errors may have been introduced in the transmission and/or reception. The processing can include decoding candidate codewords (e.g., detected blocks of information that correspond to the codewords and that may include errors) to correct, if possible, the errors, decode the one or more codewords (shown as codewords 114 upon the decoding), and accordingly determine the DCI 120 based on the codewords 114. The decoding can be implemented by an iterative decoder 260 as further described herein below. FIG. 11 illustrates a UE 1100, in accordance with some embodiments. The UE 1100 may be similar to and substantially interchangeable with a UE of FIG. 1.

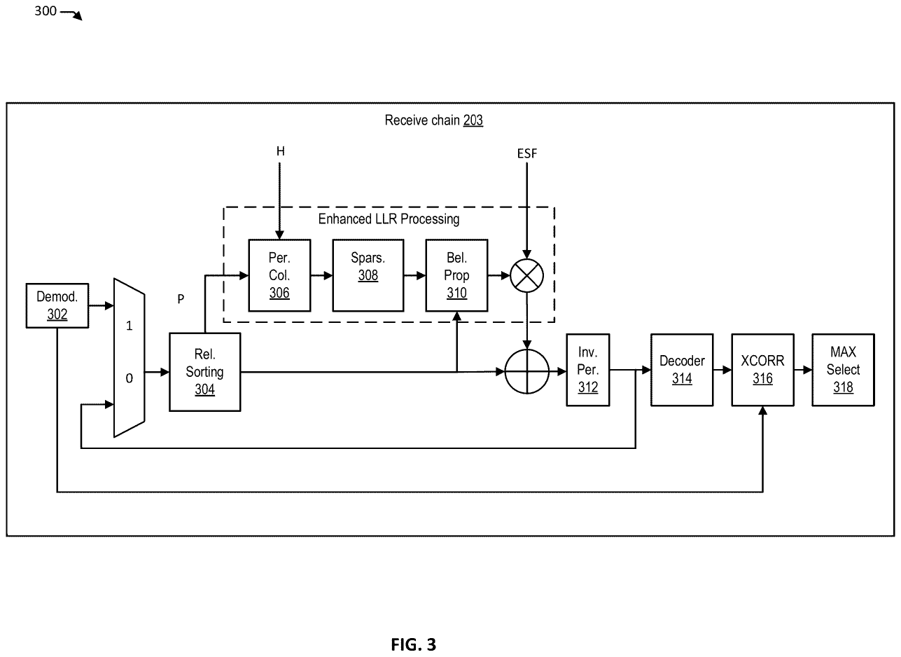

FIG. 3 is an illustration of an example receiver chain, according to one or more embodiments. A demodulator 302 (e.g., a demodulator of the second physical layer components 250) can receive an output from an RF interface (e.g., RF interface 240) and generate a channel output log likelihood ratio (LLR), which can be denoted as Λ_{ch}. The channel output LLR can be transmitted to a multiplexer, which can also receive feedback information described below. The multiplexer can generate an output (e.g., (Ain)) that is passed to a reliability sorting unit 304. The reliability sorting unit 304 can sort each channel output LLR to in order (e.g., increasing order or decreasing order) of channel reliability values (e.g., LLR magnitude). Sorting each channel output LLR can enhance the extraction of extrinsic information. The sorted channel output LLRs can be denoted as Λ_{sorted}. The sorting matrix can be denoted as matrix P such that Λ_{sorted}=P·Λᵢₙ. The sorting matrix P can be passed to a permute columns unit 306. The permute columns unit 306 can receive a first parity-check matrix (PCM) of the Reed-Muller code denoted as H_{original}. The permute columns unit 306 can process the first PCM H_{original} and the sorting matrix P to generate a second PCM denoted as H_{P}. For example, the permute columns unit 306 can rearrange the columns of the first PCM to from the second PCM.

The second PCM can be passed to a sparsification unit 308. The sparsification unit 308 can use a row reduction technique (e.g., Gaussian elimination or other row reduction technique) on the second PCM. The row reduction technique can be used to reduce the first rows (e.g., n-k rows) to identify a submatrix denoted as H_{P,GE}, which can be passed to a belief propagation unit 310 to generate soft extrinsic LLRs. The belief propagation unit can use an iterative algorithm (e.g., Bayesian network, Markov random field, or other algorithm) for decoding received messages and correcting errors introduced during transmission over noisy channels.

The belief propagation unit 310 can process the LLR Λ_{sorted} from the reliability sorting unit 304 and H_{P,GE} output soft extrinsic LLS denoted as Λ_{EXT}. The soft extrinsic LLRs can be multiplied by an extrinsic scaling factor (ESF), which can be considered a damping factor. An adder can be used to add Λ_{sorted} to generate soft extrinsic LLRs Λ_{updated}, where Λ_{updated}=Λ_{sorted}+ESF*Λ_{EXT}. The soft extrinsic LLRs Λ_{updated} can be passed to an inverse permute unit 312 to desort the soft extrinsic LLRs by Λᵢₙ=P⁻¹ Λ_{updated}, Λᵢₙ can be passed to a decoder 314. The decoder 314 can be various types of decoder, such as a Dumer FHT decoder, recursive projection aggregation (RPA) decoder, path-metric decoder, or other decoder type. A Dumer FHT decoder can use a FHT techniques to compute a Hadamard transform to reduce the computational complexity of the decoding process. The Dumer FHT decoder can recursively decompose Λᵢₙ by leveraging a hierarchical structure of the Hadamard transform. An FHT can be applied to the decomposed portion of Λᵢₙ to generate transformed values. The transformed values can be passed to a cross correlation unit 316 to calculate a cross correlation with the channel LLR Λ_{ch}. Cross correlation can be used to identify patterns or shifts between transmitted and received signals to be used for error correction. The output of the cross correlation unit 316 can be fed back to the demodulator 302, until a number of iterations is reached. The output of the cross correlation unit 316 can also be passed to a max select unit 318 that can output a codeword which has the highest cross correlation with the channel LLR Λ_{ch}. In some embodiments, the output can be the code with a minimum Euclidean distance with channel LLR Λ_{ch}.

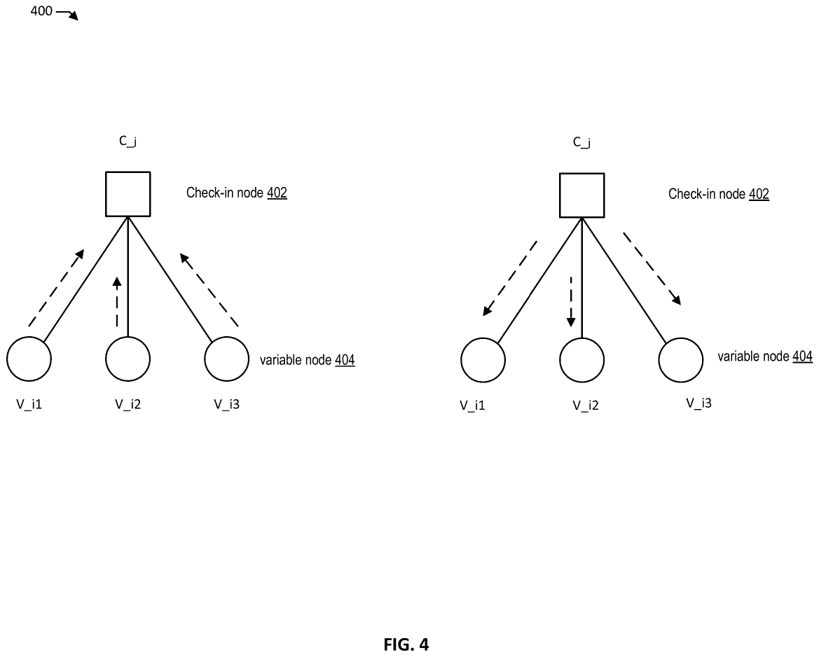

FIG. 4 is an illustration 400 of belief propagation nodes, according to one or more embodiments. Belief propagation can be a technique for updating and exchanging information with respect to probabilities of states of variables (e.g., bits) across nodes of a graph. A check node can be a parity check node that represents a parity equation in the graph. The check node can be used to determine a certain subset of variables that satisfy a parity condition. A variable node can represent a variable (e.g., bit) in a codeword.

As illustrated a check node (e.g., C_j) 402 can be connected to multiple variable nodes

$$( e . g . , {V}_{1}^{( j )} , {V}_{2}^{( j )} , … , {V}_{i}^{( j )} , … , {V}_{{d}_{j}}^{( j )} )$$

404. For a check node update (C-update), consider the check node 402 of degree dⱼ and consider the neighboring variable nodes 404. MVC_{i→j} can denote the variable to check messages sent from the neighboring variable nodes

$${V}_{i}^{( j )}$$

404 to the check node j in a previous iteration. The updated check-to-variable messages MCV_{j→i} computed by the check node 402 to

$${V}_{i}^{( j )}$$

can be given by:

$${MCV}_{j \to i} = 2 tan {h}^{- 1} [ {\prod }_{{i}^{′} ∈ {V}_{j} ∖ i} tan h ( \frac{1}{2} {MVC}_{{i}^{′} \to j} ) ] , I - 1 , 2 , … , {d}_{j}$$

For the variable node update (V-update), the variable-to-check messages can be updated at variable node Vᵢ as:

$${MVC}_{i \to j} = {L}_{i} + {\sum }_{{j}^{′} ∈ {C}_{i} ∖ j} {MCV}_{{j}^{′} \to i} ,$$

where Lᵢ denotes the LLR of bit i. At the end of the belief propagation updates, extrinsic information can be calculated as:

$${Λ}_{i , EXT} = {\sum }_{{j}^{′} ∈ {C}_{i}} {MCV}_{{j}^{′} \to i} .$$

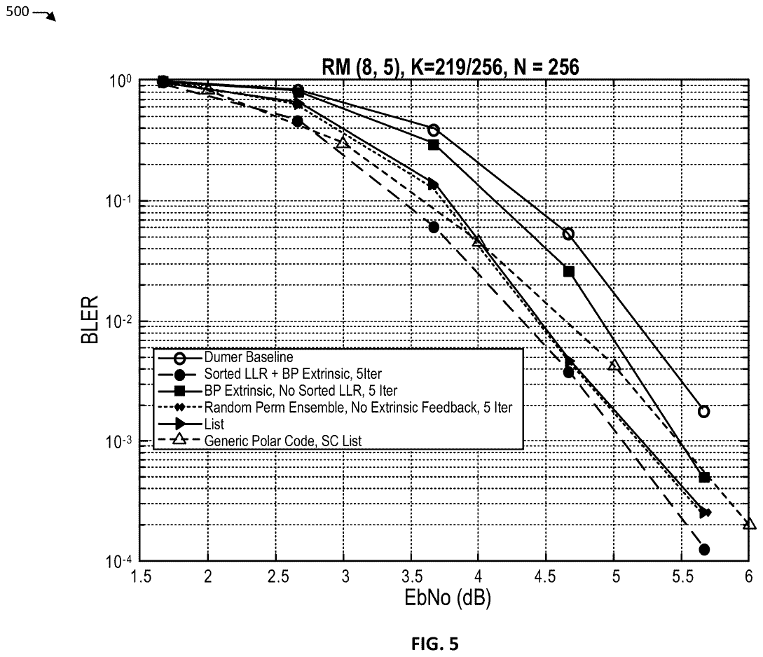

FIGS. 5, 6, 7, and 8 are provided to describe simulation results. Block error rate (BLER) decoding performance is plotted for various Reed-Muller decoders, such as tree-based recursive algorithm (Dumer's baseline decoding algorithm), path-metric based Reed-Muller decoder (Dumer's recursive list decoding), automorphism ensemble decoder, herein described iterative soft decoder (ISD) with belief propagation based extrinsic LLR update (ELU), with channel reliability sorting enabled, herein described iterative soft decoder (ISD) with belief propagation based extrinsic LLR update (ELU), without channel reliability sorting. A BLER of a generic polar code with the same coding rate is also plotted under a SC-list decoder.

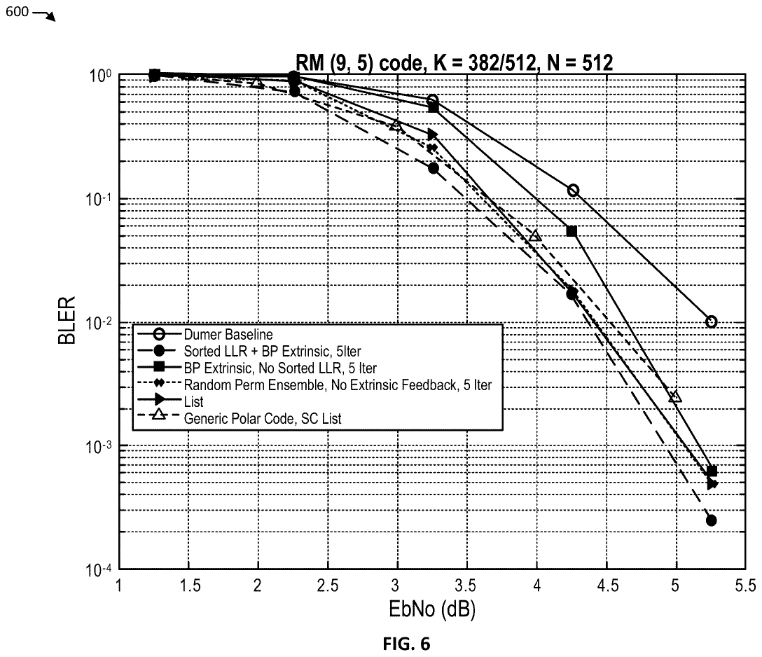

FIG. 5 illustrates a plot 500 of example simulation results, according to one or more embodiments. FIG. 6 illustrates a plot 600 of example simulation results, according to one or more embodiments. As illustrated in the plots 500, 600, the herein described ISD with belief propagation based extrinsic LLR update (ELU), with channel reliability sorting enabled can outperform the random permutation ensemble decoding. The performance difference is pronounced at a relatively low number of iterations. The herein described ISD with belief propagation based extrinsic LLR update (ELU), with channel reliability sorting enabled can also outperform list decoding. The herein described ISD with belief propagation based extrinsic LLR update (ELU), with channel reliability sorting enabled can also outperform generic polar code of the same coding rate and block length

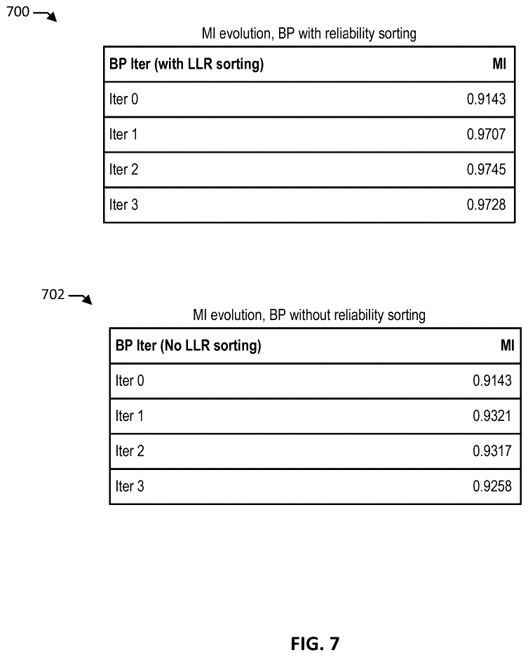

FIG. 7 illustrates tables 700, 702 of example simulation results, according to one or more embodiments. A simulation of the mutual information (MI) evolution across belief propagations is described, where MI can be between the soft LLR and the transmission codeword. It can be observed by the figures in the tables that the iterative belief propagation feedback process can lead to an improvement in MI. It can further be observed that reliability sorting can bring additional improvement in MI. The herein described technique can provide a performance enhancement of the described ISU-ELU Reed-Muller decoder from different mechanisms, such as an improved soft LLR MI from belief propagation, and larger decoding radius by using a mx XCORR selection.

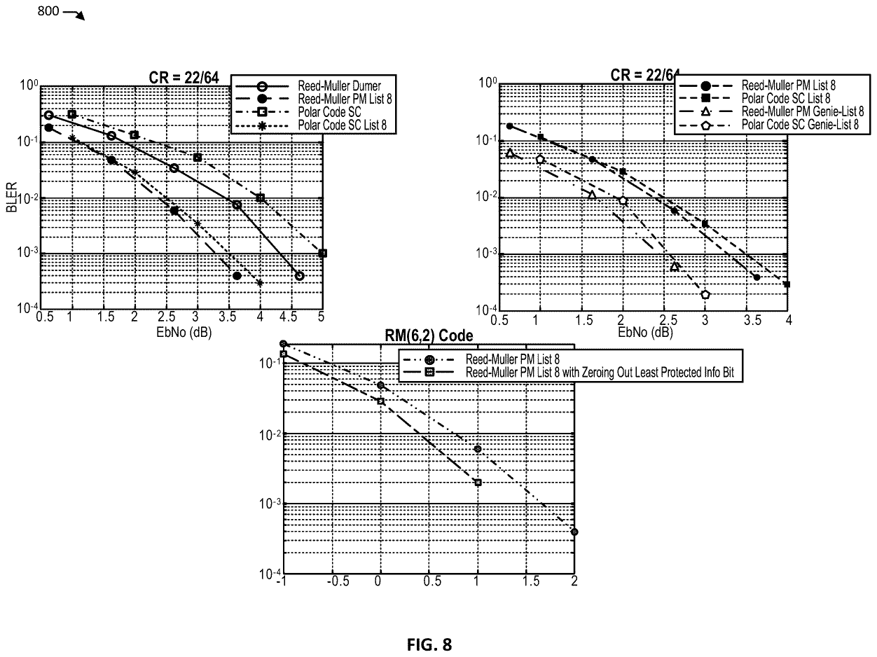

FIG. 8 illustrates plots 800 of example simulation results, according to one or more embodiments. The herein described PM-based Reed-Muller list decoder, the Reed-Muller code can demonstrate better performance than polar code with SC-list decoder, especially for short block lengths (e.g., same code rate, block length, and list size). A genie list decoder can improve the performance of a list decoder for both Reed-Muller and polar codes. The simulation results further indicate that a stronger subcode construction for rate matching can improve performance. For example, freezing (e.g., zeroing) the least reliable bit can provide a significant signal-to-noise (SNR) gain of 0.5 to 1 dB. The MI ranking for Reed-Muller repetition subcode can be MI (5,0)<MI(4,0)<MI(3,0)<(2,0), for the example Reed-Muller(6,1). The repetition subcode at the leaf nodes may only contain one information bit. The noisier bits can be set to 0 (e.g., frozen).

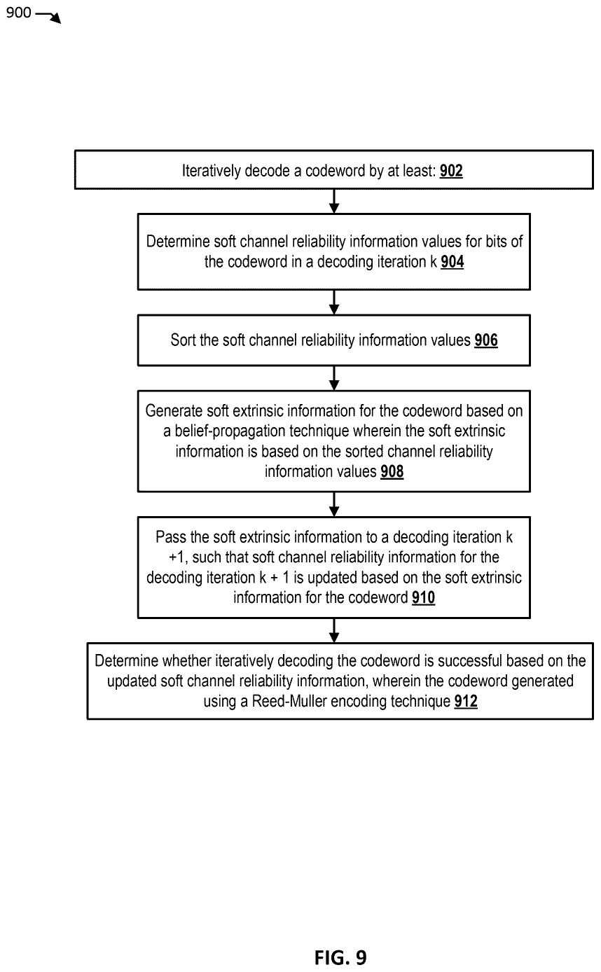

FIG. 9 is an example process 900 for soft-decision decoding, according to one or more embodiments. At 902, the process 900 can include an apparatus iteratively decoding a codeword.

Steps 904 through 910 can describe the decoding process. At 904, the process 900 can include the computing device determining soft channel reliability information values for bits of the codeword in a decoding iteration k.

At 906, the process 900 can include the apparatus sorting the soft channel reliability information values. The soft channel reliability information values can be sorted based on order of reliability to generate a first parity-check matrix. The computing device can rearrange columns of the first parity-check matrix to generate a second parity-check matrix. The soft extrinsic information can be generated based on the second parity-check matrix.

The apparatus can sparsify the second parity-check matrix to generate a third parity-check matrix. The soft extrinsic information can be generated based on the third parity-check matrix. The computing device can process, via the belief-propagation technique, the third parity-check matrix to generate an LLR, wherein the soft extrinsic information is generated based on the LLR.

At 908, the process can include the apparatus generating soft extrinsic information for the codeword based on a belief-propagation technique wherein the soft extrinsic information is based on the sorted channel reliability information values.

At 910, the process can include the apparatus passing the soft extrinsic information to a decoding iteration k+1, such that soft channel reliability information for the decoding iteration k+1 is updated based on the soft extrinsic information for the codeword.

At 912, the process 900 can include the apparatus determining whether iteratively decoding the codeword is successful based on the updated soft channel reliability information, wherein the codeword was generated using a Reed-Muller encoding technique.

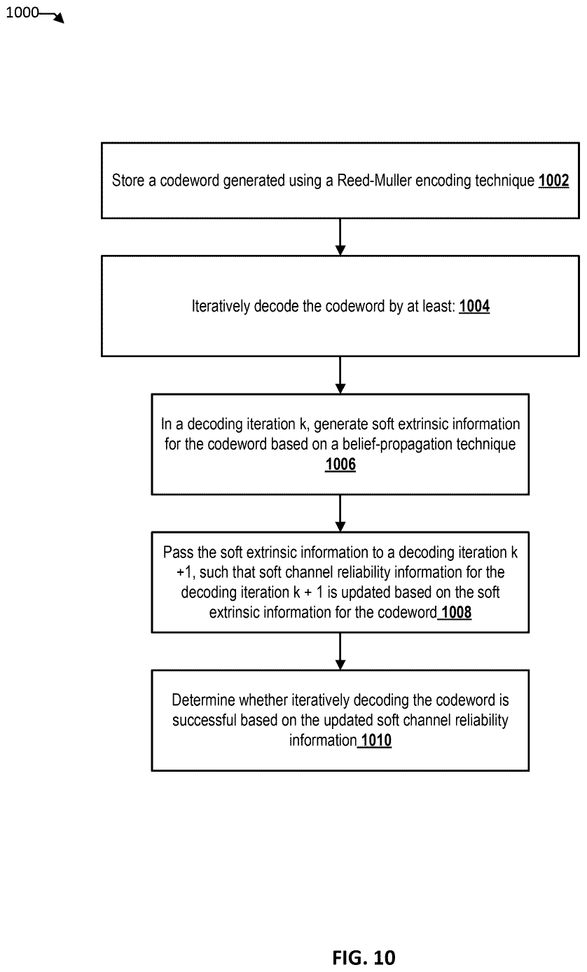

FIG. 10 is an example process 1000 for soft-decision decoding, according to one or more embodiments. At 1002, the process 1000 can include an apparatus storing a codeword generated using a Reed-Muller encoding technique.

At 1004, the process 1000 can include the apparatus iteratively decode the codeword.

Steps 1006 through 1010 describe a decoding process. At 1006, the apparatus can in a decoding iteration k, generate soft extrinsic information for the codeword based on a belief-propagation technique.

The apparatus can perform the belief-propagation technique, as specified by a first parity-check matrix, on an LLR associated with a variable node to generate an updated LLR. The apparatus can further perform the belief-propagation technique, as specified by a second parity-check matrix, on the updated LLR. The soft extrinsic information can be generated based on the second parity-check matrix. The apparatus can perform the belief-propagation technique, as specified by a third parity-check matrix, on the updated LLR, The soft extrinsic information can be generated based on the third parity-check matrix.

At 1008, the process 1000 can include the apparatus passing the soft extrinsic information to a decoding iteration k+1, such that soft channel reliability information for the decoding iteration k+1 is updated based on the soft extrinsic information for the codeword.

At 1010, the process 1000 can include the apparatus determining whether iteratively decoding the codeword is successful based on the updated soft channel reliability information.

FIG. 11 illustrates receive components 1100 of the UE 1106, in accordance with some embodiments. The receive components 1100 may include an antenna panel 1104 that includes a number of antenna elements. The panel 1104 is shown with four antenna elements, but other embodiments may include other numbers.

The antenna panel 1104 may be coupled to analog beamforming (BF) components that include a number of phase shifters 1108(1)-1108(4). The phase shifters 1108(1)-1108(4) may be coupled with a radio-frequency (RF) chain 1113. The RF chain 1113 may amplify a receive analog RF signal, downconvert the RF signal to baseband, and convert the analog baseband signal to a digital baseband signal that may be provided to a baseband processor for further processing.

In various embodiments, control circuitry, which may reside in a baseband processor, may provide BF weights (e.g., W1-W4), which may represent phase shift values, to the phase shifters 1108(1)-1108(4) to provide a receive beam at the antenna panel 1104. These BF weights may be determined based on the channel-based beamforming.

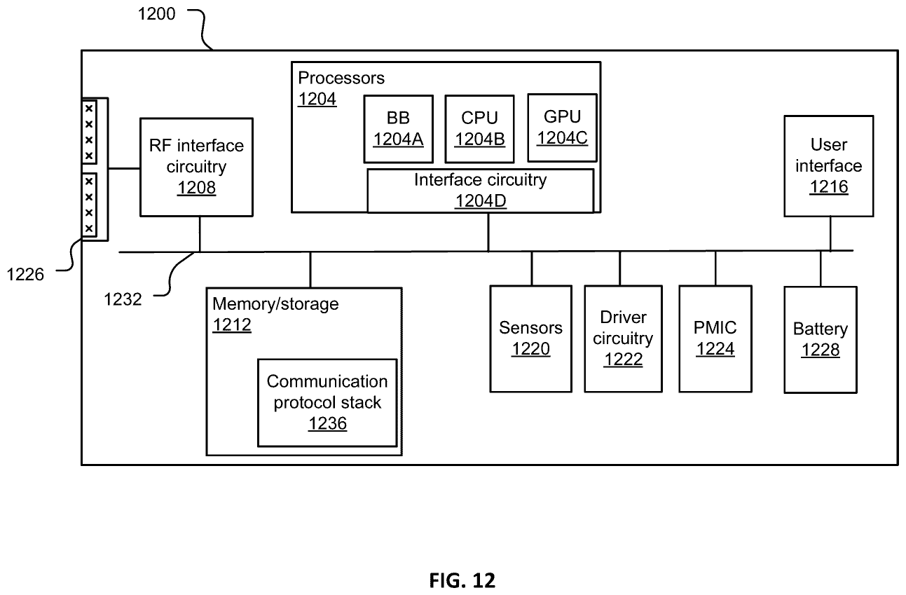

FIG. 12 illustrates a UE 1200, in accordance with some embodiments. The UE 1200 may be similar to and substantially interchangeable with UE 102 of FIG. 1.

The processors 1204 may include processor circuitry such as, for example, baseband processor circuitry (BB) 1204A, central processor unit circuitry (CPU) 1204B, and graphics processor unit circuitry (GPU) 1204C. The processors 1204 may include any type of circuitry or processor circuitry that executes or otherwise operates computer-executable instructions, such as program code, software modules, or functional processes from memory/storage 1212 to cause the UE 1200 to perform delay-adaptive operations as described herein. The processors 1204 may also include interface circuitry 1204D to communicatively couple the processor circuitry with one or more other components of the UE 1200.

In some embodiments, the baseband processor circuitry 1204A may access a communication protocol stack 1236 in the memory/storage 1212 to communicate over a 3GPP compatible network. In general, the baseband processor circuitry 1204A may access the communication protocol stack 1236 to: perform user plane functions at a PHY layer, MAC layer, RLC layer, PDCP layer, SDAP layer, and PDU layer; and perform control plane functions at a PHY layer, MAC layer, RLC layer, PDCP layer, RRC layer, and a NAS layer. In some embodiments, the PHY layer operations may additionally/alternatively be performed by the components of the RF interface circuitry 1208.

The baseband processor circuitry 1204A may generate or process baseband signals or waveforms that carry information in 3GPP-compatible networks. In some embodiments, the waveforms for NR may be based on cyclic prefix OFDM (CP-OFDM) in the uplink or downlink, and discrete Fourier transform spread OFDM (DFT-S-OFDM) in the uplink.

The memory/storage 1212 may include one or more non-transitory, computer-readable media that includes instructions (for example, communication protocol stack 1236) that may be executed by one or more of the processors 1204 to cause the UE 1200 to perform various delay-adaptive operations described herein.

The memory/storage 1212 includes any type of volatile or non-volatile memory that may be distributed throughout the UE 1200. In some embodiments, some of the memory/storage 1212 may be located on the processors 1204 themselves (for example, memory/storage 1212 may be part of a chipset that corresponds to the baseband processor circuitry 1204A), while other memory/storage 1212 is external to the processors 1204 but accessible thereto via a memory interface. The memory/storage 1212 may include any suitable volatile or non-volatile memory such as, but not limited to, dynamic random access memory (DRAM), static random access memory (SRAM), erasable programmable read only memory (EPROM), electrically erasable programmable read only memory (EEPROM), Flash memory, solid-state memory, or any other type of memory device technology.

The RF interface circuitry 1208 may include transceiver circuitry and a radio frequency front module (RFEM) that allows the UE 1200 to communicate with other devices over a radio access network. The RF interface circuitry 1208 may include various elements arranged in transmit or receive paths. These elements may include, for example, switches, mixers, amplifiers, filters, synthesizer circuitry, and control circuitry.

In the receive path, the RFEM may receive a radiated signal from an air interface via antenna 1226 and proceed to filter and amplify (with a low-noise amplifier) the signal. The signal may be provided to a receiver of the transceiver that down-converts the RF signal into a baseband signal that is provided to the baseband processor of the processors 1204.

In the transmit path, the transmitter of the transceiver up-converts the baseband signal received from the baseband processor and provides the RF signal to the RFEM. The RFEM may amplify the RF signal through a power amplifier prior to the signal being radiated across the air interface via the antenna 1226.

In various embodiments, the RF interface circuitry 1208 may be configured to transmit/receive signals in a manner compatible with NR access technologies.

The antenna 1226 may include antenna elements to convert electrical signals into radio waves to travel through the air and to convert received radio waves into electrical signals. The antenna elements may be arranged into one or more antenna panels. The antenna 1226 may have antenna panels that are omnidirectional, directional, or a combination thereof to enable beamforming and multiple input, multiple output communications. The antenna 1226 may include microstrip antennas, printed antennas fabricated on the surface of one or more printed circuit boards, patch antennas, or phased array antennas. The antenna 1226 may have one or more panels designed for specific frequency bands including bands in FR1 or FR2.

The user interface 1216 includes various input/output (I/O) devices designed to enable user interaction with the UE 1200. The user interface 1216 includes input device circuitry and output device circuitry. Input device circuitry includes any physical or virtual means for accepting an input including, inter alia, one or more physical or virtual buttons (for example, a reset button), a physical keyboard, keypad, mouse, touchpad, touchscreen, microphones, scanner, headset, or the like. The output device circuitry includes any physical or virtual means for showing information or otherwise conveying information, such as sensor readings, actuator position(s), or other like information. Output device circuitry may include any number or combinations of audio or visual display, including, inter alia, one or more simple visual outputs/indicators (for example, binary status indicators such as light emitting diodes (LEDs) and multi-character visual outputs, or more complex outputs such as display devices or touchscreens (for example, liquid crystal displays (LCDs), LED displays, quantum dot displays, and projectors), with the output of characters, graphics, multimedia objects, and the like being generated or produced from the operation of the UE 1200.

The sensors 1220 may include devices, modules, or subsystems whose purpose is to detect events or changes in their environment and send the information (sensor data) about the detected events to some other device, module, or subsystem. Examples of such sensors include inertia measurement units comprising accelerometers, gyroscopes, or magnetometers; microelectromechanical systems or nanoelectromechanical systems comprising 3-axis accelerometers, 3-axis gyroscopes, or magnetometers; level sensors; flow sensors; temperature sensors (for example, thermistors); pressure sensors; barometric pressure sensors; gravimeters; altimeters; image capture devices (for example, cameras or lensless apertures); light detection and ranging sensors; proximity sensors (for example, infrared radiation detector and the like); depth sensors; ambient light sensors; ultrasonic transceivers; and microphones or other like audio capture devices.

The driver circuitry 1222 may include software and hardware elements that operate to control particular devices that are embedded in the UE 1200, attached to the UE 1200, or otherwise communicatively coupled with the UE 1200. The driver circuitry 1222 may include individual drivers allowing other components to interact with or control various input/output (I/O) devices that may be present within, or connected to, the UE 1200. For example, driver circuitry 1222 may include a display driver to control and allow access to a display device, a touchscreen driver to control and allow access to a touchscreen interface, sensor drivers to obtain sensor readings of sensors 1220 and control and allow access to sensors 1220, drivers to obtain actuator positions of electro-mechanic components or control and allow access to the electro-mechanic components, a camera driver to control and allow access to an embedded image capture device, audio drivers to control and allow access to one or more audio devices.

The PMIC 1224 may manage power provided to various components of the UE 1200. In particular, with respect to the processors 1204, the PMIC 1224 may control power-source selection, voltage scaling, battery charging, or DC-to-DC conversion.

A battery 1228 may power the UE 1200, although in some examples the UE 1200 may be mounted deployed in a fixed location and may have a power supply coupled to an electrical grid. The battery 1228 may be a lithium ion battery, a metal-air battery, such as a zinc-air battery, an aluminum-air battery, a lithium-air battery, and the like. In some implementations, such as in vehicle-based applications, the battery 1228 may be a typical lead-acid automotive battery.

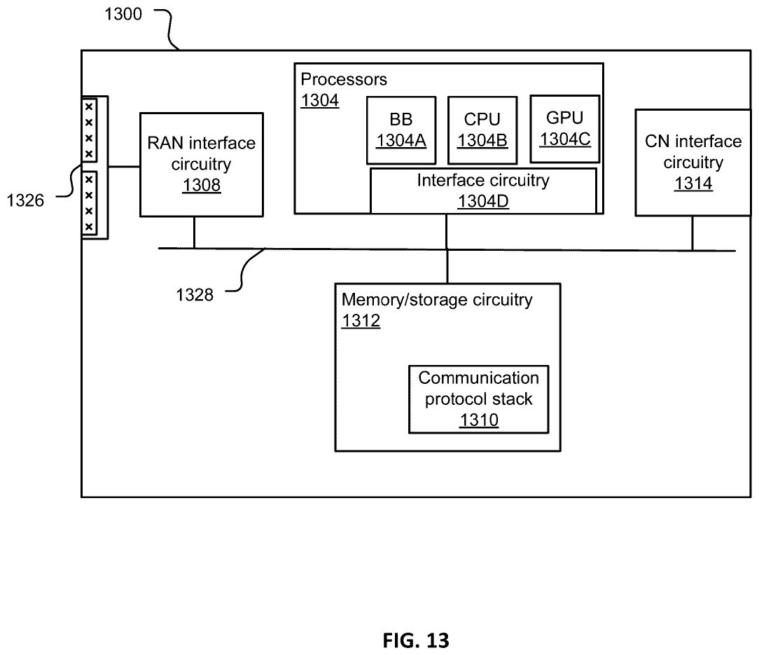

FIG. 13 illustrates a network device 1300 in accordance with some embodiments. The network device 1300 may be similar to and substantially interchangeable with base station 108 or a device of the core network or an external data network.

The network device 1300 may include processors 1304, RF interface circuitry 1308 (if implemented as a base station), core network (CN) interface circuitry 1314, memory/storage circuitry 1312, and antenna structure 1326.

The components of the network device 1300 may be coupled with various other components over one or more interconnects 1328.

The processors 1304, RF interface circuitry 1308, memory/storage circuitry 1312 (including communication protocol stack 1310), antenna structure 1326, and interconnects 1328 may be similar to like-named elements shown and described with respect to FIG. 12.

The processors 1304 may include processor circuitry such as, for example, baseband processor circuitry (BB) 1304A, central processor unit circuitry (CPU) 1304B, and graphics processor unit circuitry (GPU) 1304C. The processors 1304 may include any type of circuitry or processor circuitry that executes or otherwise operates computer-executable instructions, such as program code, software modules, or functional processes from memory/storage circuitry 1312 to cause the UE 1300 to perform delay-adaptive operations as described herein. The processors 1304 may also include interface circuitry 1304D to communicatively couple the processor circuitry with one or more other components of the network device 1300.

The CN interface circuitry 1314 may provide connectivity to a core network, for example, a 5th Generation Core network (5GC) using a 5GC-compatible network interface protocol such as carrier Ethernet protocols, or some other suitable protocol. Network connectivity may be provided to/from the network device 1300 via a fiber optic or wireless backhaul. The CN interface circuitry 1314 may include one or more dedicated processors or FPGAs to communicate using one or more of the aforementioned protocols. In some implementations, the CN interface circuitry 1314 may include multiple controllers to provide connectivity to other networks using the same or different protocols.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

For one or more embodiments, at least one of the components set forth in one or more of the preceding figures may be configured to perform one or more operations, techniques, processes, or methods as set forth in the example section below. For example, the baseband circuitry as described above in connection with one or more of the preceding figures may be configured to operate in accordance with one or more of the examples set forth below. For another example, circuitry associated with a UE, base station, or network element as described above in connection with one or more of the preceding figures may be configured to operate in accordance with one or more of the examples set forth below in the example section.

### EXAMPLES

In the following sections, further example embodiments are provided.

Any of the above-described examples may be combined with any other example (or combination of examples), unless explicitly stated otherwise. The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A method comprising:
iteratively decoding a codeword by at least:
determining soft channel reliability information values for bits of the codeword in a decoding iteration k,
sorting the soft channel reliability information values,
generating soft extrinsic information for the codeword based on a belief-propagation technique wherein the soft extrinsic information is based on the sorted channel reliability information values, and
passing the soft extrinsic information to a decoding iteration k+1, such that soft channel reliability information for the decoding iteration k+1 is updated based on the soft extrinsic information for the codeword; and
determining whether iteratively decoding the codeword is successful based on the updated soft channel reliability information, wherein the codeword was generated using a Reed-Muller encoding technique.

2. The method of claim 1, wherein the soft channel reliability information values are sorted based on order of reliability.

3. The method of claim 1, wherein the soft channel reliability information values are sorted based on order of reliability to generate a first parity-check matrix, wherein the method further comprises rearranging columns of the first parity-check matrix to generate a second parity-check matrix, and wherein the soft extrinsic information is generated based on the second parity-check matrix.

4. The method of claim 3, wherein the method further comprises:
sparsifying the second parity-check matrix to generate a third parity-check matrix, wherein the soft extrinsic information is generated based on the third parity-check matrix.

5. The method of claim 4, wherein the method further comprises:
processing, via the belief-propagation technique, the third parity-check matrix to generate a log-likely ratio (LLR), wherein the soft extrinsic information is generated based on the LLR.

6. The method of claim 4, wherein the belief-propagation technique comprises:
performing a first parity-check based on an LLR associated with a variable node to generate an updated LLR; and
performing a second parity-check based on the updated LLR, and wherein the soft extrinsic information is generated based on the second parity-check.

7. The method of claim 6, wherein the method further comprises:
generating updated soft information based on an extrinsic scaling factor (ESF) and the updated LLR, wherein decoding the codeword is based on the updated soft information.

8. The method of claim 1, wherein decoding the codeword comprises:
processing the codeword via a Dumer-Fast Hadmard Transform (FHT) technique based on an order of a Reed-Muller code, a length of the codeword, and updated soft information, wherein the updated soft information is based on the soft extrinsic information.

9. The method of claim 8, wherein the method further comprises:
processing, via a cross-correlation (XCORR) technique, an output generated using the Dumer-FHT technique, wherein determining whether iteratively decoding the codeword is successful is further based on the output.

10. The method of claim 1, wherein the soft extrinsic information comprises a LLR associated with the codeword.

11. An apparatus comprising:
processor circuitry configured to:
store a codeword generated using a Reed-Muller encoding technique;
iteratively decode the codeword by at least:
in a decoding iteration k, generate soft extrinsic information for the codeword based on a belief-propagation technique, and
pass the soft extrinsic information to a decoding iteration k+1, such that soft channel reliability information for the decoding iteration k+1 is updated based on the soft extrinsic information for the codeword; and
determine whether iteratively decoding the codeword is successful based on the updated soft channel reliability information; and
interface circuitry coupled with the processor circuitry enable communication.

12. The apparatus of claim 11, wherein the processor circuitry is further configured to:
determine soft channel reliability information values for bits of the codeword; and
sort the soft channel reliability information values based on order of reliability, wherein the soft extrinsic information is based on the sorted channel reliability information values.

13. The apparatus of claim 11, wherein the processor circuitry is further configured to:
determine soft channel reliability information values for bits of the codeword;
generate a first parity-check matrix;
sort the soft channel reliability information values based on order of reliability; and
rearrange columns of the first parity-check matrix to generate a second parity-check matrix, wherein the soft extrinsic information is generated based on the second parity-check matrix.

14. The apparatus of claim 13, wherein the processor circuitry is further configured to:
sparsify the second parity-check matrix to generate a third parity-check matrix, wherein the soft extrinsic information is generated based on the third parity-check matrix.

15. The apparatus of claim 10, wherein the processor circuitry is further configured to:
process, via the belief-propagation technique, the third parity-check matrix to generate an LLR, wherein the soft extrinsic information is generated based on the LLR.

16. The apparatus of claim 10, wherein the belief-propagation technique comprises:
performing the belief-propagation technique, as specified by a first parity-check matrix, on an LLR associated with a variable node to generate an updated LLR; and
performing the belief-propagation technique, as specified by a second parity-check matrix, on the updated LLR, and wherein the soft extrinsic information is generated based on the second parity-check matrix; and
performing the belief-propagation technique, as specified by a third parity-check matrix, on the updated LLR, and wherein the soft extrinsic information is generated based on the third parity-check matrix.

17. The apparatus of claim 16, wherein the processor circuitry is further configured to:
generate updated soft information based on an extrinsic scaling factor (ESF) and the updated LLR, wherein decoding the codeword is based on the updated soft information.

18. One or more computer-readable media having stored thereon a sequence of instructions that, when executed, cause processor circuitry to:
store a codeword generated using a reed-muller encoding technique;
iteratively decode the codeword by at least:
in a decoding iteration k, generating soft extrinsic information for the codeword based on a belief-propagation technique, and
passing the soft extrinsic information to a decoding iteration k+1, such that soft channel reliability information for the decoding iteration k+1 is updated based on the soft extrinsic information for the codeword; and
determine whether iteratively decoding the codeword is successful based on the updated soft channel reliability information.

19. The one or more computer-readable media of claim 18, wherein thereon a sequence of instructions that, when executed, further cause the processor circuitry to:
determine soft channel reliability information values for bits of the codeword; and
sort the soft channel reliability information values based on order of reliability, wherein the soft extrinsic information is based on the sorted channel reliability information values.

20. The one or more computer-readable media of claim 18, wherein decoding the codeword comprises:
processing the codeword via a Dumer-Fast Hadmard Transform (FHT) technique based on an order of a Reed-Muller code, a length of the codeword, and updated soft information, wherein the updated soft information is based on the soft extrinsic information.
